(19) United States
(12) Patent Application Publication
(10) Pub. No.: US 2013/0058499 A1
(43) Pub. Date: Mar. 7, 2013

(54) INFORMATION PROCESSING APPARATUS AND INFORMATION PROCESSING METHOD

(71) Applicants: Ryota Matsumoto, Tokyo (JP); Takayuki Akai, Chiba (JP); Kazuya Ishii, Tokyo (JP)

(72) Inventors: Ryota Matsumoto, Tokyo (JP); Takayuki Akai, Chiba (JP); Kazuya Ishii, Tokyo (JP)

(21) Appl. No.: 13/595,960

(22) Filed: Aug. 27, 2012

(30) Foreign Application Priority Data
Sep. 1, 2011 (JP) 2011-191091

(51) Int. Cl. H03G 5/00; H04R 1/02

(52) U.S. Cl. 381/98; 381/386

(57) ABSTRACT

An information processing apparatus includes: a sound source configured to generate sound waves; and a housing configured to incorporate the sound source and include a first main surface and a second main surface opposite to each other, the first main surface including a groove-like concave portion configured to communicate in one axial direction along the second main surface, and an opening for transmitting sound waves of the sound source, the opening being provided in an area of the concave portion and at a position offset from the middle in the one axial direction of the first main surface.

### BACKGROUND

The present disclosure relates to an information processing apparatus that incorporates a sound source and to an information processing method.

Some audio reproducing apparatuses, especially ones that put emphasis on portability, are equipped with a speaker and a microphone. Such a speaker and a microphone are used during a use of these audio reproducing apparatuses as a voice recorder or a telephone. Also, such a speaker is used while a user is listening to music or recorded voice reproduced by an audio reproducing apparatus without earphones.

In this manner, a speaker of an audio reproducing apparatus that puts emphasis on portability is expected to be mounted at a position away from a position at which a microphone is mounted as much as possible so as to prevent howling. With respect to a microphone, since a user interface of an audio reproducing apparatus is arranged on one main surface in consideration of usability as a telephone, an opening for transmitting speaker sounds to the outside of a housing (speaker opening) is often provided on a surface other than the main surface.

In Japanese Patent Application Laid-open No. 2009-296052 (hereinafter, referred to as Patent Document 1), for example, a portable telephone having a speaker opening provided on a surface of a housing, which is opposite to one main surface on which a user interface is provided, is described. The portable telephone is equipped with a projection-shaped battery lid finger hooking unit that projects from a surface portion on the back surface side at a position slightly away from a central portion of the back surface. When the portable telephone is put on a desk with the user interface facing upward to be used, the battery lid finger hooking unit and one side of the portable terminal having an approximately rectangular flat shape are touched with the desk. This generates a space between the back surface of the portable telephone and the desk. The speaker opening is provided in an area corresponding to the space of the back surface so as not to close speaker outputs. In this manner, in Patent Document 1, a battery finger hooking unit for an existing battery lid is provided to have a shape projected from a surface portion of the back surface so that a space is generated not to close speaker outputs without providing a dedicated convex portion. In the portable terminal disclosed in Patent Document 1, when the portable terminal is put on a desk, the space between the back surface of the housing and the desk substantially radially extends when viewed from a position of a speaker hole.

### SUMMARY

In an audio reproducing apparatus that puts emphasis on portability, however, there is a limitation of a sound quality to be obtained and the reproducibility of audible sounds having a low frequency due to the size restriction of a housing. That is, it is desirable to enhance a quality of output sounds with the size restriction in an audio reproducing apparatus that puts emphasis on portability, especially an audio reproducing apparatus that incorporates a sound source.

In consideration of the above-mentioned issues, there is a need for providing an information processing apparatus and an information processing method capable of enhancing a quality of output sounds with a simple structure.

An information processing apparatus according to an embodiment of the present disclosure includes a sound source configured to generate sound waves; and a housing configured to incorporate the sound source and include a first main surface and a second main surface opposite to each other, the first main surface including a groove-like concave portion configured to communicate in one axial direction along the second main surface, and an opening for transmitting sound waves of the sound source, the opening being provided in an area of the concave portion and at a position offset from the middle in the one axial direction of the first main surface.

In the embodiment of the present disclosure, since the concave portion configured to communicate in one axial direction is provided on the first main surface of the housing, when the information processing apparatus is put on a mounting surface such as a surface of a desk with the second main surface facing up, a tunnel portion is formed between the first main surface and the mounting surface. This provides directivity to sound waves that have passed through the opening. Since the concave portion is provided at a position offset from the middle in one axial direction of the first main surface, a difference is generated between a distance from the opening to one aperture end of the tunnel portion and a distance from the opening to the other aperture end of the tunnel portion. This provides a difference between a maximum wave length of solid-borne sounds on one aperture end side and a maximum wave length of solid-borne sounds on the other aperture end side. Since sounds that have passed through the opening become two sounds having different maximum wave lengths, sounds having a stereo perception are obtained from one sound.

The second main surface may include a screen for user interface.

The concave portion may have a cross sectional shape that is uniform throughout a length of the one axial direction when viewed from the one axial direction. This prevents sound waves to be transmitted through the opening from being diffused due to irregular reflection in the tunnel portion between the first main surface and the mounting surface. This provides desired directivity of sound waves. When the directivity of sound waves is ensured, two solid-borne sounds having different maximum wave lengths can be generated reliably.

The information processing apparatus may further include a sound signal processing unit configured to generate a sound signal to be supplied to the sound source; a detection unit configured to detect, during generation of a sound signal by the sound signal processing unit, mounting of the information processing apparatus with the second main surface facing up; and a control unit configured to control, when the mounting is detected by the detection unit, the sound signal processing unit to change property of sounds generated from the sound source.

The control unit may control the sound signal processing unit to increase a sound pressure in a predetermined frequency band.

This allows a clearer stereophonic effect to be obtained.

An information processing method according to another embodiment of the present disclosure is for an information processing apparatus including a sound source configured to generate sound waves, a housing configured to incorporate the sound source and include a first main surface and a second main surface opposite to each other, the first main surface including a groove-like concave portion configured to communicate in one axial direction along the second main surface, and an opening for transmitting sound waves of the sound source, the opening being provided in an area of the concave portion and at a position offset from the middle in the one axial direction of the first main surface, and a sound signal processing unit configured to generate a sound signal to be supplied to the sound source, the information processing method including: detecting, during generation of a sound signal by the sound signal processing unit, mounting of the information processing apparatus with the second main surface facing up; and controlling the sound signal processing unit to change property of sounds generated from the sound source.

As mentioned above, according to the present disclosure, it is possible to enhance a quality of output sounds of an information processing apparatus with a simple structure.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a perspective view in which an information processing apparatus according to a first embodiment of the present disclosure is viewed from a screen side;

FIG. 2 is a plain view in which the information processing apparatus shown in FIG. 1 is viewed from a back surface side;

FIG. 3 is a side view in which the information processing apparatus shown in FIG. 2 is viewed from a direction of an arrow III;

FIG. 4 is a perspective view showing a state in which the information processing apparatus shown in FIG. 1 is mounted on a mounting surface such as a surface of a desk;

FIG. 5 is a side view showing a state in which a user holds the information processing apparatus shown in FIG. 1 sideways;

FIG. 6 is a view showing a detailed structure of a back surface of the information processing apparatus shown in FIG. 1;

FIG. 7 is a view for explaining an effect by an off-center position of an opening for a speaker of the information processing apparatus shown in FIG. 1;

FIG. 8 is a block diagram showing a hardware structure of the information processing apparatus shown in FIG. 1;

FIG. 9 is a back view showing an information processing apparatus according to a modification example 1 of the present disclosure;

FIG. 10 is a back view showing an information processing apparatus according to a modification example 2 of the present disclosure;

FIG. 11 is a back view showing an information processing apparatus according to a modification example 3 of the present disclosure;

FIG. 12 is a back view showing an information processing apparatus according to a modification example 4 of the present disclosure;

FIG. 13 is a side view showing an information processing apparatus according to a modification example 5 of the present disclosure;

FIG. 14 is a side view showing a state in which the information processing apparatus shown in FIG. 1 is mounted on a desk; and

FIG. 15 is a flowchart associated with control processing for audio outputs of the information processing apparatus shown in FIG. 1.

### DETAILED DESCRIPTION OF EMBODIMENTS

Hereinafter, an embodiment of the present disclosure will be described with reference to the drawings.

### [Outline of Embodiment]

The embodiment relates to an information processing apparatus having a speaker, such as an audio reproducing apparatus, a portable telephone, a game machine, and a remote controller.

Recently, information processing apparatuses that put emphasis on portability have been often equipped with a speaker and a microphone. Such a speaker and a microphone are used during a use of these information processing apparatuses as a voice recorder or a telephone. Also, such a speaker is used while a user is listening to music or recorded voice reproduced by an information processing apparatus without earphones. Since sounds from a speaker are necessary to be caught by a microphone as little as possible, an opening for the speaker and an opening for the microphone are generally provided at positions separated from each other as much as possible.

In consideration of the above-mentioned issues, however, when the opening for the speaker is provided on a surface opposite to a surface on which the opening for the microphone is provided, the opening for the speaker is closed by the mounting surface in a situation in which the information processing apparatus is put on, for example, a desk with the surface on which the microphone is provided facing up, causing sounds to be indistinct. In this regard, a structure has been considered in which a convex portion is provided on the surface on which the opening for the speaker is provided so as to space the opening from the mounting surface.

An information processing apparatus according to the embodiment not only ensures a space between a surface on which an opening for a speaker is provided and a mounting surface so as not to close the opening, but also provides a structure in which 3D sounds are provided by propagating sound waves having constant directivity through the space. More specifically, the structure includes a groove-like concave portion provided on the surface on which the opening for the speaker is provided to communicate in one axial direction along the surface, and an opening provided at a position offset from the middle in the one axial direction in the concave portion.

The groove-like concave portion contributes to formation of a tunnel-like space that communicates in the one axial direction between the surface on which the opening for the speaker is provided and the mounting surface. The tunnel-like space provides directivity to a direction in which sound waves to be transmitted from the opening propagate. Since the opening is provided at a position offset from the middle in the one axial direction in the concave portion, there is a difference between a distance from the opening to one end of the tunnel-like space (one side of housing) and a distance from the opening to the other end (the other side of housing). The distance is a value that determines a maximum wave length of solid-borne sounds. Therefore, solid-borne sounds having different maximum wave lengths are delivered from both ends of the tunnel-like space, which generates a pseudo stereophonic effect.

Hereinafter, an information processing apparatus according to the embodiment will be described in detail.

### First Embodiment

### [External Package Structure of Information Processing Apparatus]

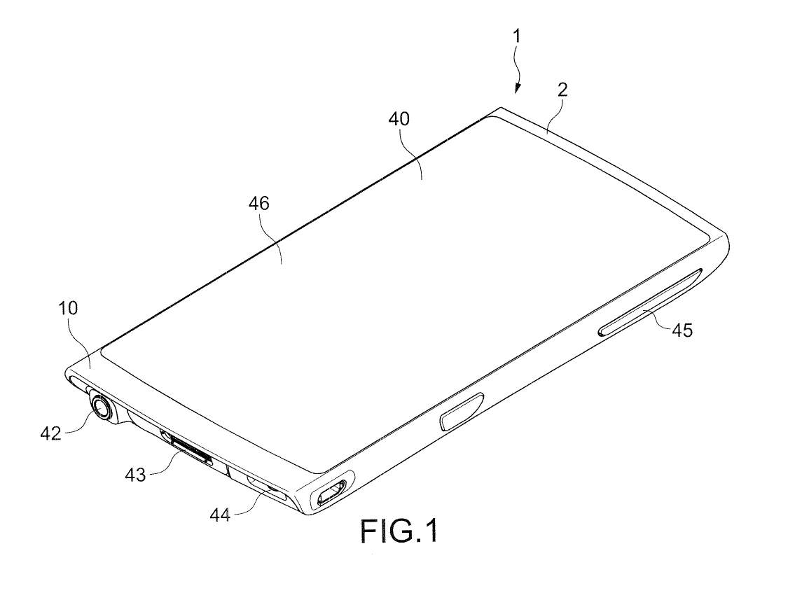

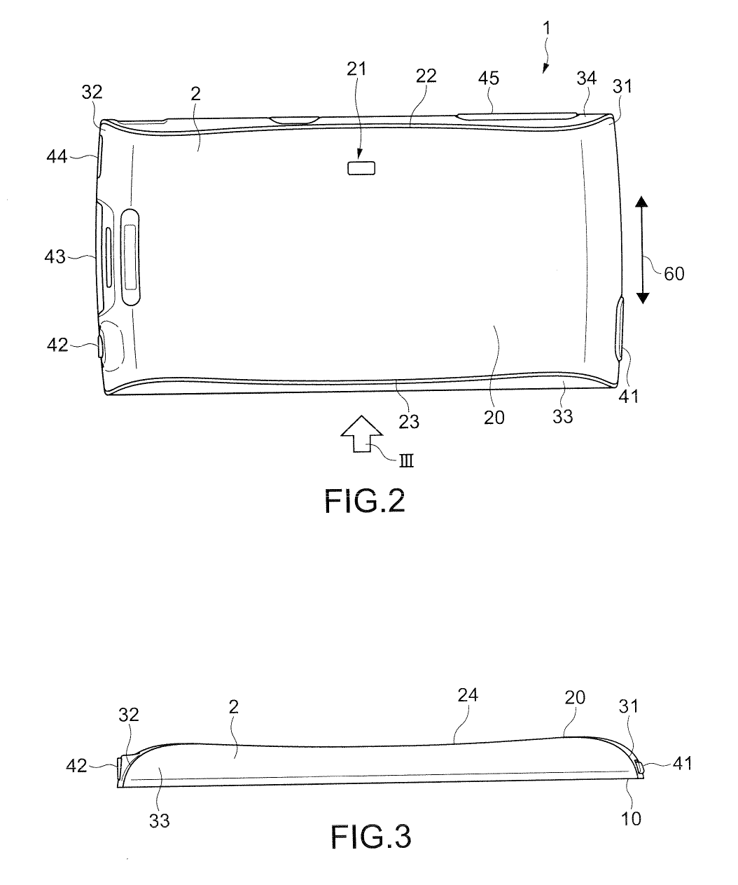

FIG. 1 is a perspective view in which an information processing apparatus according to a first embodiment of the present disclosure is viewed from a side of a screen for user interface. FIG. 2 is a plain view in which the information processing apparatus shown in FIG. 1 is viewed from a back surface side opposite to the side of the screen for user interface.

The present disclosure is specifically applicable to mobile type audio reproducing apparatuses as an information processing apparatus, and generally to information processing apparatuses having a speaker, such as a mobile telephone, a game machine, and a remote controller, as other examples.

As shown in FIG. 1 and FIG. 2, an information processing apparatus 1 includes a housing 2, a touch screen 46 having a screen for user interface 40, and a speaker module that is a sound source (not shown).

The speaker module is a general speaker configured to generate sound waves by driving of a diaphragm.

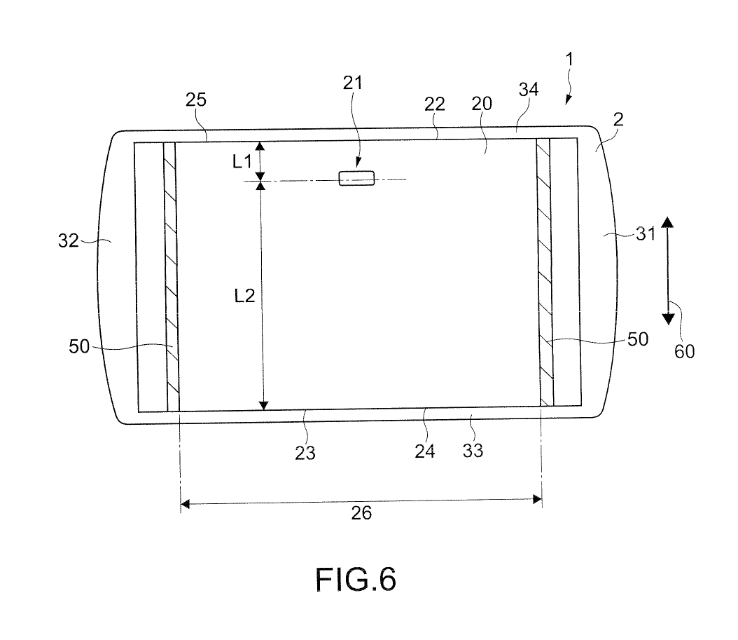

The housing 2 incorporates the speaker module and holds the touch screen 46. The housing 2 includes a first main surface 20 having an approximately rectangular flat shape that is on a back surface side, a second main surface 10 opposite to the first main surface 20, and four side surfaces 31 to 34. The first main surface 20 includes a concave portion 24, and an opening for speaker 21 that is provided on an area of the concave portion 24 (portion 25 in FIG. 6). The concave portion 24 has a groove shape that communicates in one axial direction along the second main surface 10 (direction 60 in FIG. 2). The opening for speaker 21 is for transmitting sound waves generated from the speaker module, and is provided at a position offset from a middle position in one axial direction 60 of the first main surface 20 in an area of the concave portion 24.

The touch screen 46 includes, for example, a touch panel as an input apparatus and a liquid crystal panel as a display unit. The touch panel of the touch screen 46 is a transparent pressure-sensitive type input apparatus that is superimposed and mounted on a surface of the liquid crystal panel. The touch panel accepts an input operation to an arbitrary point on the screen 40 by a user. When the user performs a gesture operation such as a touch operation or a drag operation on the touch panel with a finger or a touch pen, the touch panel detects coordinates of a position corresponding to the gesture operation. As the input apparatus, any position detection device other than a touch panel may also be used regardless of whether it is a contact type or non-contact type, as long as a gesture operation to a display unit by a user is detectable.

The liquid crystal panel of the touch screen 46 includes the screen 40 such as a liquid crystal display and a display driving unit configured to control a display on the screen 40. When audio such as music is reproduced by the information processing apparatus 1, information on the music being reproduced and GUI elements for volume adjustment or music selection are displayed on the screen for user interface 40 so that volume adjustment, music selection, and the like can be performed on the screen for user interface by a gesture operation.

In addition, on the plurality of side surfaces 31 to 34 of the information processing apparatus 1, a power button 41 configured to control On/Off of the power of the information processing apparatus 1, an insertion opening for power plug 42, an insertion opening for IC card 43, a volume adjustment switch 45, and the like are provided.

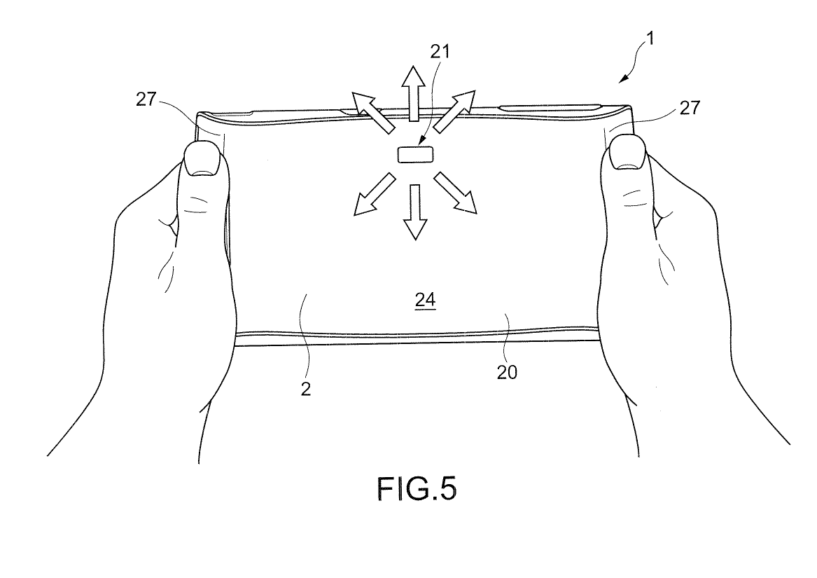

FIG. 5 is a side view showing a state in which a user holds the information processing apparatus 1 sideways.

In this manner, both sides of the concave portion 24 in the first main surface 20 that is on a back surface side of the housing 2 are used as holding units 27 and 27, when a user holds the information processing apparatus 1 with both hands.

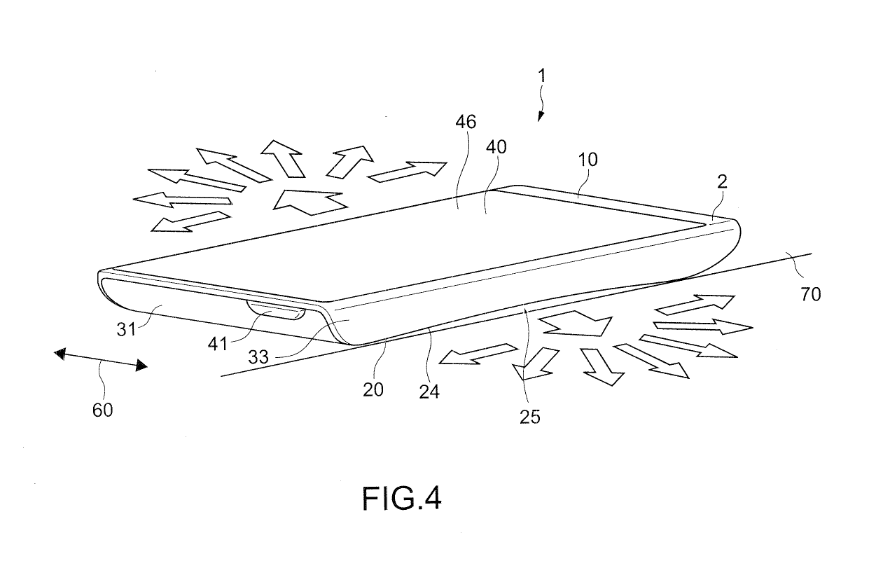

FIG. 3 is a side view in which the information processing apparatus 1 shown in FIG. 2 is viewed from the arrow III. FIG. 4 is a perspective view showing a state in which the information processing apparatus 1 is put on a mounting surface 70 such as a surface of a desk. FIG. 14 is a side view showing the whole of a mounting state of the information processing apparatus 1 on a desk.

As shown in FIG. 3, FIG. 4, and FIG. 14, the first main surface 20 of the housing 2 includes the groove-like concave portion 24 along the one axial direction 60. The concave portion 24 provides a tunnel-like space (tunnel portion 25) formed between the first main surface 20 and the mounting surface 70, when the information processing apparatus 1 is mounted on the mounting surface 70 such as a surface of a desk with the screen for user interface 40 (second main surface 10) facing up. A cross sectional shape viewed from the one axial direction 60 of the tunnel portion 25 is uniform throughout the length. When the cross sectional shape is not uniform throughout the length of the one axial direction 60, sound waves transmitted from the opening for speaker 21 are diffused due to irregular reflection occurring on the unevenness of the inside of the tunnel portion 25. Therefore, the cross sectional shape viewed from the one axial direction 60 of the tunnel portion 25 is desirable to be uniform throughout the length, and the surface of the concave portion 24 is desirable to be a surface without unevenness.

FIG. 6 is a view showing a detailed structure of the first main surface 20 that is a back surface of the information processing apparatus 1.

When the information processing apparatus 1 is put on the mounting surface 70 such as a surface of a desk with the screen for user interface 40 (second main surface 10) facing up, the first main surface 20 and the mounting surface 70 are touched with each other at two contact areas 50 marked with diagonal lines in the figure that are on both sides of the concave portion 24. Therefore, an area sandwiched in between the two contact areas 50 is designed to be a tunnel portion area 26 in which the tunnel portion 25 is formed. Since the concave portion 24 is provided so as to communicate in the one axial direction 60, both ends of the tunnel portion 25 formed between the concave portion 24 and the mounting surface 70 are opened. Hereinafter, one aperture of the tunnel portion 25 will be referred to as “first tunnel aperture end 22” and the other aperture thereof will be referred to as “second tunnel aperture end 23”.

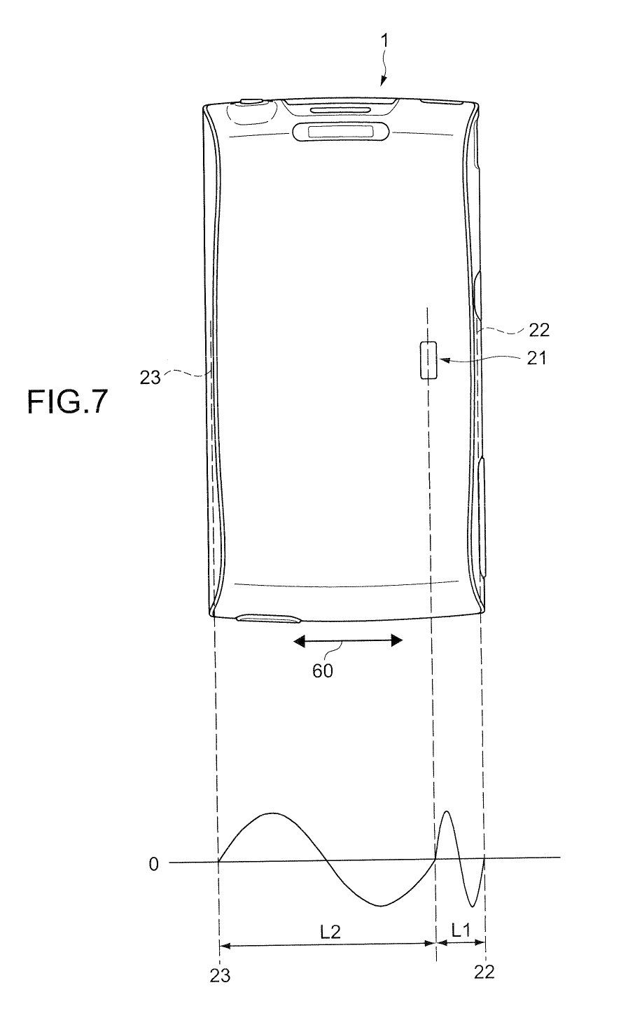

As shown in FIG. 6, the opening for speaker 21 is provided at a position offset from a middle position in the one axial direction 60. In this manner, since the opening for speaker 21 exists at a position offset from a middle position in the one axial direction 60 of the concave portion 24, a difference is provided between a distance L1 from the first tunnel aperture end 22 of the tunnel portion 25 to the center of the opening for speaker 21 and a distance L2 from the second tunnel aperture end 23 of the tunnel portion 25 to the center of the opening for speaker 21. Therefore, as shown in FIG. 7, a difference is generated between a maximum wave length of solid-borne sounds on the first tunnel aperture end 22 side of the tunnel portion 25 and a maximum wave length of solid-borne sounds on the second tunnel aperture end 23 side of the tunnel portion 25.

Since L1<L2 is true, compared to the maximum wave length of solid-borne sounds on the first tunnel aperture end 22 side, the maximum wave length of solid-borne sounds on the second tunnel aperture end 23 side is longer by (L2−L1). In this manner, since sounds that have passed through one speaker module through the opening 21 become two sounds having different maximum wave lengths, sounds having a stereo perception can be obtained even from monaural sounds.

Assuming a case of L1=L2, which means when the opening for speaker 21 is at the middle in the one axial direction 60 of the concave portion 24, there is a case that two solid-borne sounds are added to one air-borne sound and a sound amplitude of wave length components originally having a large amplitude becomes excessively large to cover other sounds of wave length components having a comparatively small amplitude. According to the embodiment, since a difference is provided between the maximum wave length of solid-borne sounds on the first tunnel aperture end 22 side of the tunnel portion 25 and the maximum wave length of solid-borne sounds from the second tunnel aperture end 23 side of the tunnel portion 25, an amplitude is prevented from being too large in a wave length band of the difference so as to reduce covering the sounds of wave length components having a small amplitude.

### [Hardware Structure of Information Processing Apparatus]

Hereinafter, a hardware structure of the information processing apparatus 1 will be described.

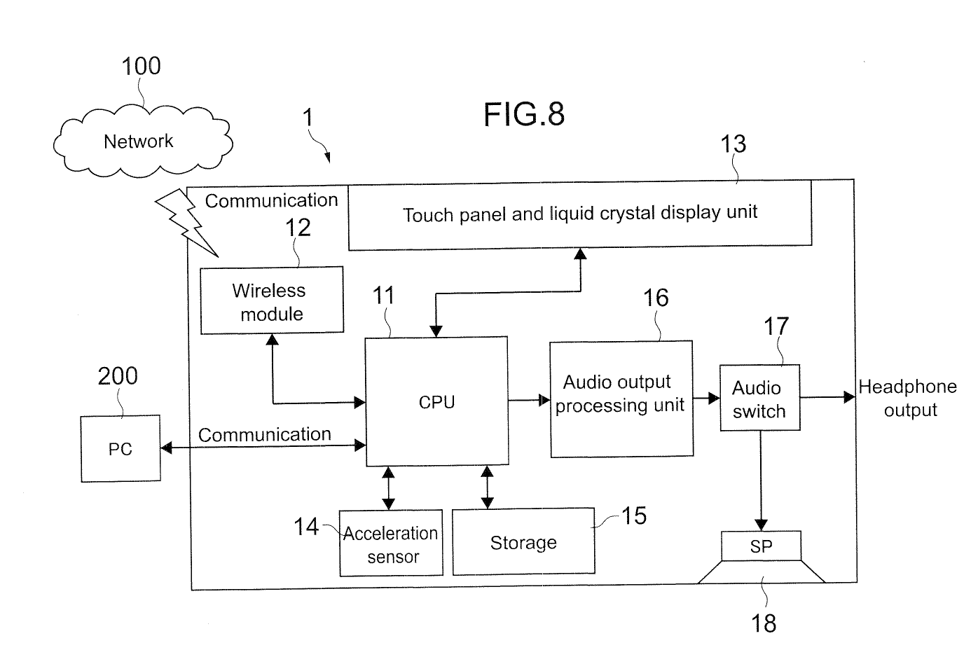

FIG. 8 is a diagram showing a hardware structure of the information processing apparatus 1 according to the embodiment.

The information processing apparatus 1 includes a CPU (Central Processing Unit) 11, a wireless module 12, a touch panel and liquid crystal display unit 13, an acceleration sensor 14, a storage 15, an audio output processing unit 16, an audio switch 17, and a speaker module 18.

The CPU 11 performs various types of processing according to programs stored in a memory (not shown) or the storage 15. Also, the CPU 11 is connectable to a PC 200 that is a host through an interface such as a USB (Universal Serial Bus).

The wireless module 12 performs connection to a network 100 such as the Internet by wireless communication such as short-range wireless communication.

The touch panel and liquid crystal display unit 13 composes the touch screen 46 that is an interface to a user.

The acceleration sensor 14 is a sensor configured to detect acceleration in three axes (X axis, Y axis, and Z axis) directions. A detection signal of the acceleration sensor 14 is supplied to the CPU 11 and processed as information to detect that, for example, the information processing apparatus 1 is mounted on the mounting surface 70 such as a surface of a desk with the screen for user interface 40 (second main surface 10) facing up. Instead of the acceleration sensor 14, for example, a gyro sensor configured to detect an angle to a gravity direction is usable.

The storage 15 is a storage device in which, for example, audio data such as music, video data, content such as document data, and application programs are stored.

The audio output processing unit 16 performs processing for generating audio output signals, such as demodulation of the audio data supplied from the CPU 11 and digital-to-analog (D/A) conversion processing.

The audio switch 17 switches a supply destination for the audio output signals from the audio output processing unit 16 between a headphone terminal and the speaker module 18, according to a switch instruction input from a user by operation on the touch screen 46.

### [Action of Information Processing Apparatus]

In the information processing apparatus 1 according to the embodiment, when audio output signals from the audio output processing unit 16 are supplied to the speaker module 18 through the audio switch 17, the CPU 11 controls the audio output processing unit 16 to provide a change to property of sounds generated from the speaker module 18 in a state where the information processing apparatus 1 is mounted on the mounting surface 70 such as a surface of a desk with the screen for user interface 40 (second main surface 10) facing up, as shown in FIG. 14. Hereinafter, the processing will be described.

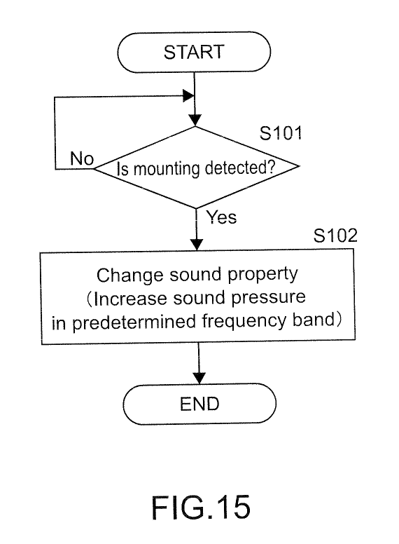

FIG. 15 is a flowchart associated with control processing for audio outputs of the information processing apparatus 1.

The CPU 11 detects occurrence of an event of the mounting of the information processing apparatus 1 on the mounting surface 70 with the screen for user interface 40 (second main surface 10) facing up, on the basis of outputs of the acceleration sensor 14 (step S101). When occurrence of the event is detected (YES in step S101), the CPU 11 controls the audio output processing unit 16 to provide a change to property of sounds generated from the speaker module 18. More specifically, the CPU 11 changes gain to a predetermined frequency band and controls the audio output processing unit 16 to increase a sound pressure in the frequency band (step S102).

The predetermined frequency band is desired to be, for example, a frequency band corresponding to a difference between the maximum wave length of solid-borne sounds on the first tunnel aperture end 22 side of the tunnel portion 25 and the maximum wave length of solid-borne sounds on the second tunnel aperture end 23 side of the tunnel portion 25, or a band in which a frequency band having a predetermined margin is added to above and below the frequency band. This increases a difference in sound pressure between the solid-borne sounds on the first tunnel aperture end 22 side of the tunnel portion 25 and the solid-borne sounds on the second tunnel aperture end 23 side of the tunnel portion 25, which provides a clearer stereophonic effect. The predetermined frequency band is, however, not limited to that.

Next, modification examples will be described. Hereinafter, the same reference symbols will be used in the same structure as the above-mentioned embodiment, and explanation thereof will be omitted.

The speaker module 18 may be of a stereo type or a monaural type.

A position of the opening for speaker 21 may be any position offset from the middle in the one axial direction 60 of the concave portion 24, and the offset amount may be desirably set to be as large as possible in consideration of notability of a stereophonic effect. When an appropriate level of the stereophonic effect is expected, however, there is no limitation.

In consideration of the above-mentioned issues, modification examples described below can be provided as examples associated with a position of the opening for speaker 21. These are, however, just a part of examples.

### Modification Example 1

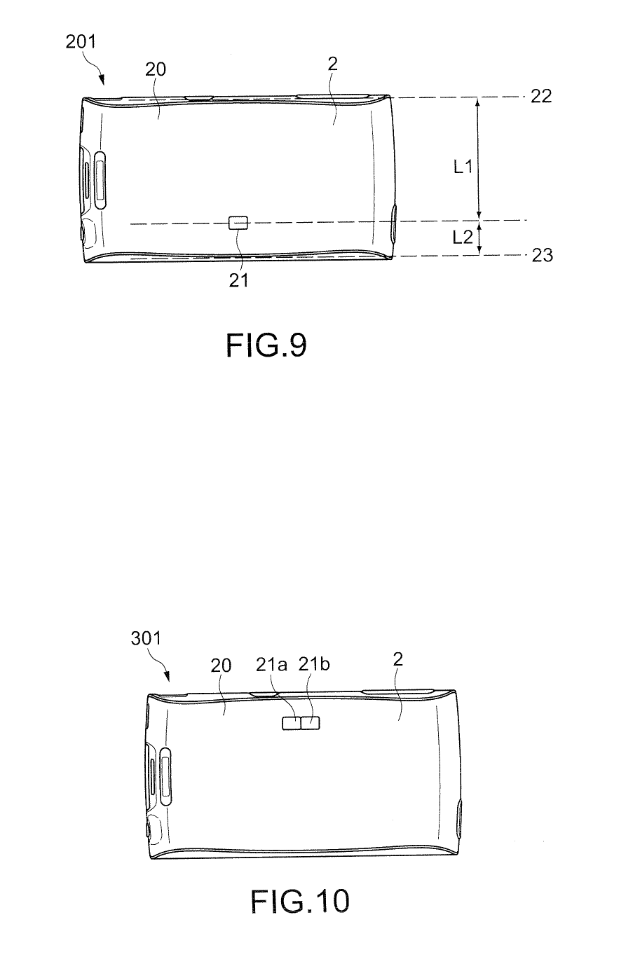

FIG. 9 is an example in which a relationship between the distance L1 from the first tunnel aperture end 22 of the tunnel portion 25 to the center of the opening for speaker 21 and the distance L2 from the second tunnel aperture end 23 of the tunnel portion 25 to the center of the opening for speaker 21 is changed from L1<L2, which is applied in the above embodiment, to L1>L2.

### Modification Example 2

FIG. 10 is a location example of openings 21a and 21b in the case that two stereo-type speakers are employed. In this manner, the openings 21a and 21b for the two respective speakers may be arranged at positions offset from the middle position in the one axial direction 60, similarly to the first embodiment.

### Modification Example 3

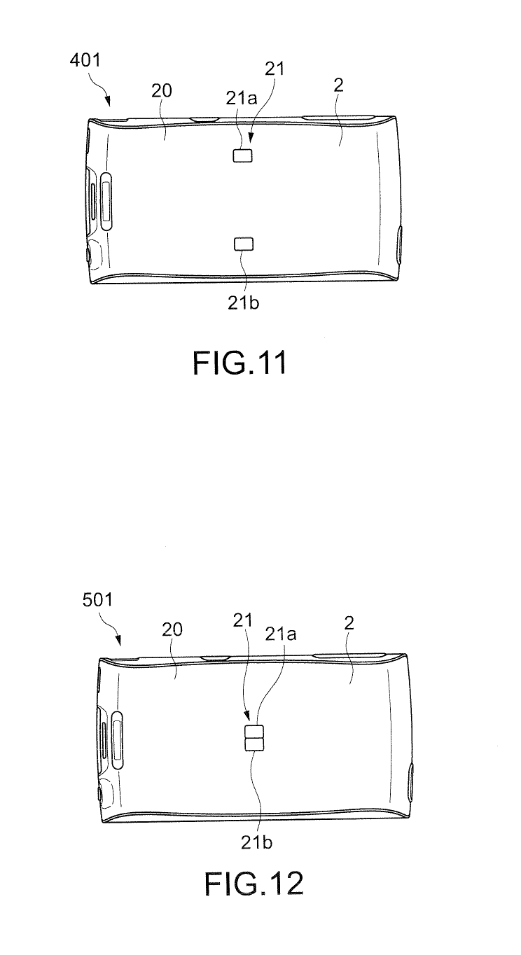

FIG. 11 is another location example of openings 21a and 21b in the case that two stereo-type speaker modules are employed. In this manner, the openings 21a and 21b for the two respective speaker modules may be arranged at positions offset from the middle position in the one axial direction 60 by the same distance in different directions respectively.

### Modification Example 4

Moreover, since the offset amount is selectable according to a stereophonic effect to be expected, as shown in FIG. 12, for example, openings 21a and 21b for two respective speaker modules may be arranged at positions slightly offset from the middle position in the one axial direction 60.

### Modification Example 5

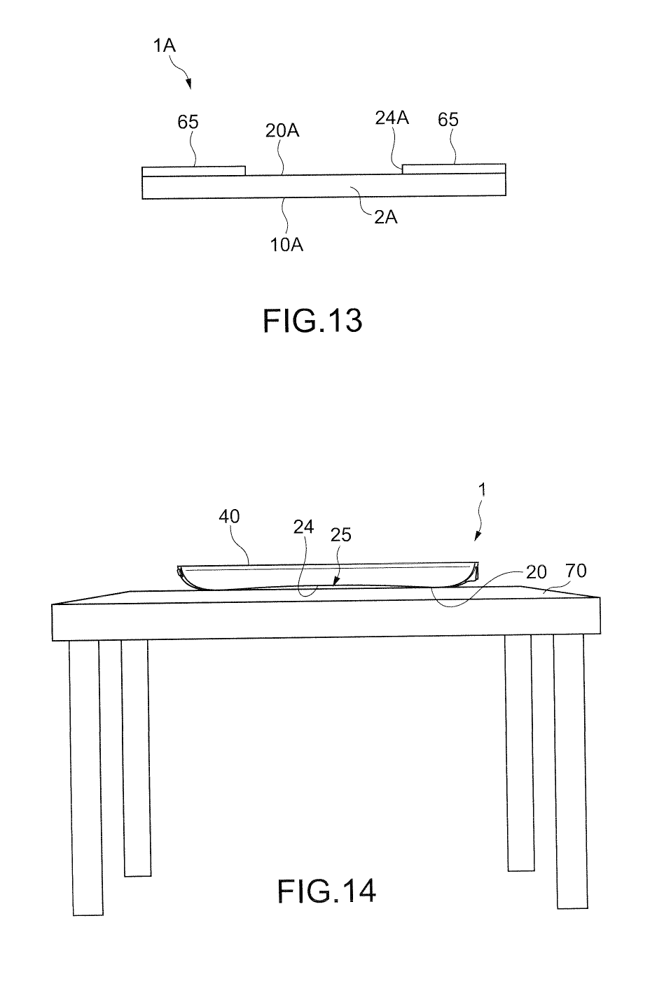

In the above-mentioned embodiment, the concave portion 24 of the first main surface 20 has a curvature surface, but there is no limitation to that. As an information processing apparatus 1A shown in FIG. 13, for example, two convex portions 65 and 65 may be separately arranged along one axial direction on a first main surface 20A of a housing 2A so that a concave portion 24A having a rectangular cross sectional shape may be formed by these convex portions 65 and 65 and the first main surface 20A.

The present disclosure may also be applied to the following structure.

(1) An information processing apparatus, including:
a sound source configured to generate sound waves; and
a housing configured to incorporate the sound source and include a first main surface and a second main surface opposite to each other, the first main surface including
   a groove-like concave portion configured to communicate in one axial direction along the second main surface, and
   an opening for transmitting sound waves of the sound source, the opening being provided in an area of the concave portion and at a position offset from the middle in the one axial direction of the first main surface.
      (2) The information processing apparatus according to (1), in which
the second main surface includes a screen for user interface.
   (3) The information processing apparatus according to (1) or (2), in which
the concave portion has a cross sectional shape that is uniform throughout a length of the one axial direction when viewed from the one axial direction.
   (4) The information processing apparatus according to any one of (1) to (3), further including
a sound signal processing unit configured to generate a sound signal to be supplied to the sound source;
a detection unit configured to detect, during generation of a sound signal by the sound signal processing unit, mounting of the information processing apparatus with the second main surface facing up; and
a control unit configured to control, when the mounting is detected by the detection unit, the sound signal processing unit to change property of sounds generated from the sound source.

The present disclosure is not limited to embodiments described above, and various modifications can be realized in the scope of technical ideas according to the present disclosure.

The present disclosure contains subject matter related to that disclosed in Japanese Priority Patent Application JP 2011-191091 filed in the Japan Patent Office on Sep. 1, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An information processing apparatus, comprising:
a sound source configured to generate sound waves; and
a housing configured to incorporate the sound source and include a first main surface and a second main surface opposite to each other, the first main surface including
a groove-like concave portion configured to communicate in one axial direction along the second main surface, and
an opening for transmitting sound waves of the sound source, the opening being provided in an area of the concave portion and at a position offset from the middle in the one axial direction of the first main surface.

2. The information processing apparatus according to claim 1, wherein
the second main surface includes a screen for user interface.

3. The information processing apparatus according to claim 2, wherein
the concave portion has a cross sectional shape that is uniform throughout a length of the one axial direction when viewed from the one axial direction.

4. The information processing apparatus according to claim 3, further comprising:
a sound signal processing unit configured to generate a sound signal to be supplied to the sound source;
a detection unit configured to detect, during generation of a sound signal by the sound signal processing unit, mounting of the information processing apparatus with the second main surface facing up; and
a control unit configured to control, when the mounting is detected by the detection unit, the sound signal processing unit to change property of sounds generated from the sound source.

5. The information processing apparatus according to claim 4, wherein
the control unit controls the sound signal processing unit to increase a sound pressure in a predetermined frequency band.

6. An information processing method for an information processing apparatus including
a sound source configured to generate sound waves,
a housing configured to incorporate the sound source and include a first main surface and a second main surface opposite to each other, the first main surface including
a groove-like concave portion configured to communicate in one axial direction along the second main surface, and
an opening for transmitting sound waves of the sound source, the opening being provided in an area of the concave portion and at a position offset from the middle in the one axial direction of the first main surface, and
a sound signal processing unit configured to generate a sound signal to be supplied to the sound source, the information processing method comprising:
detecting, during generation of a sound signal by the sound signal processing unit, mounting of the information processing apparatus with the second main surface facing up; and
controlling the sound signal processing unit to change property of sounds generated from the sound source.
